(19) United States
(12) Patent Application Publication
(10) Pub. No.: US 2011/0298725 A1
(43) Pub. Date: Dec. 8, 2011

(54) TOUCH PANEL MANUFACTURING METHOD AND STRUCTURE THEREOF

(75) Inventors: YU-CHOU YEH, TAOYUAN COUNTY (TW); KUO-HSIUNG TUNG, TAOYUAN COUNTY (TW)

(73) Assignee: J TOUCH CORPORATION, TAOYUAN COUNTY (TW)

(21) Appl. No.: 12/847,304

(22) Filed: Jul. 30, 2010

(30) Foreign Application Priority Data
Jun. 3, 2010 (TW) 099117997

(51) Int. Cl. H03K 17/94; G06F 3/041; H01J 9/00

(52) U.S. Cl. 345/173; 445/24; 341/20

(57) ABSTRACT

In a touch panel manufacturing method and a structure thereof, an icon layer is formed at the periphery of a transparent substrate surface, and a plurality of first conducting wires and a plurality of second conducting wires are installed on a first lateral surface and a second lateral surface of the icon layer respectively, and the first conducting wires are covered onto transparent substrate surface, and a plurality of insulating blocks are arranged with an interval from each other on the first conducting wires, and finally a plurality of first sensing blocks and a plurality of second sensing blocks are formed, and the plurality of first sensing blocks are covered onto the first conducting wires on both sides of the insulating blocks, and the plurality of second sensing blocks are connected to other two sides of the insulating blocks.

### 1. CROSS-REFERENCE TO RELATED APPLICATIONS

This non-provisional application claims priority under 35 U.S.C. §119(a) on Patent Application No(s). 099117997 filed in Taiwan, R.O.C. on Jun. 3, 2010, the entire contents of which are hereby incorporated by reference.

### BACKGROUND OF THE INVENTION

1. Field of the Invention

The present invention generally relates to a touch panel manufacturing procedure and a touch panel structure, and more particularly to a touch panel manufacturing method and a structure thereof capable of simplifying the manufacturing procedure of sensing electrodes.

2. Description of the Related Art

Touch panel is generally divided into resistive, capacitive, surface acoustic wave and optical (infrared) touch panel, and the resistive touch panel is used most extensively, and the capacitive touch panel comes next. The capacitive touch panel is further divided into projective capacitive touch panel and surface capacitive touch panel. The advantages of the capacitive touch panel include water resistance, scratch resistance, high light transmittance, and wide applicable manufacturing temperature range. Although the capacitive touch panel has a relatively high price, yet the capacitive touch panel gradually enters into the market of touch panels for small-size display devices as the technology matures with time.

For example, P.R.C. Pat. No. CN1754141 and its foreign counterpart U.S. Pat. No. 6,970,160 entitled “Lattice touch-sensing system” relates to a lattice touch-sensing system for detecting a position of a touch on a touch-sensing surface. The lattice touch-sensing system may include two capacitive sensing layers, separated by an insulating material, where each layer consists of substantially parallel conducting elements, and the conducting elements of the two sensing layers are substantially orthogonal to each other. Each element may comprise a series of diamond shaped patches that are connected together with narrow conductive rectangular strips. Each conducting element of a given sensing layer is electrically connected at one or both ends to a lead line of a corresponding set of lead lines. A control circuit may also be included to provide an excitation signal to both sets of conducting elements through the corresponding sets of lead lines, to receive sensing signals generated by sensor elements when a touch on the surface occurs, and to determine a position of the touch based on the position of the affected bars in each layer.

However, the aforementioned patent includes at least two sensing layers, and each sensing layer must be manufactured separately in a production. In general, the sensing layer is manufactured by sputtering, etching or laminating after pre-shaping, so that the sensing layers may be physically or chemically changed by the later manufacturing easily, such that the yield rate of the touch panel drops. Furthermore, the sensing layers are connected to the diamond shaped patches by narrow conductive rectangular strips, so that a large number of intervals exist between the diamond shaped patches. Since a display device is installed under the touch panel for displaying images, the image may be affected by the intervals and produces diffraction and interference when the image is projected to the outside.

### SUMMARY OF THE INVENTION

In view of the aforementioned requirements, the inventor of the present invention based on years of experience in the related industry and conducted extensive researches, and finally developed a touch panel manufacturing method and a structure thereof.

Therefore, it is a primary objective of the invention to overcome the aforementioned shortcomings and deficiencies of the prior art by providing a touch panel manufacturing method and a touch panel structure capable of simplifying the manufacturing procedure of capacitive touch panels.

Another objective of the present invention is to provide a touch panel manufacturing method and a touch panel structure capable of simplifying the manufacturing procedure of sensing electrodes.

Another objective of the present invention is to provide a touch panel manufacturing method and a touch panel structure capable of installing a sensing electrode with a plurality sensing directions.

To achieve the aforementioned objective, the present invention provides a touch panel manufacturing method and a structure thereof, wherein an icon layer is disposed at the periphery of a transparent substrate surface, and a plurality of first conducting wires and a plurality of second conducting wires are installed on a first lateral surface and a second lateral surface of the icon layer respectively, and the first conducting wires are covered onto transparent substrate surface, and a plurality of insulating blocks are arranged with an interval from each other on the first conducting wires, and finally a plurality of first sensing blocks and a plurality of second sensing blocks are formed, and the plurality of first sensing blocks are covered onto the first conducting wires on both sides of the insulating blocks, and the plurality of second sensing blocks are connected to other two sides of the insulating blocks.

The touch panel manufacturing method and the touch panel structure of the present invention further comprises disposing an icon layer at the periphery of a transparent substrate surface, forming a transparent insulating layer in an area of the transparent substrate surface, and installing a plurality of first conducting wires and a plurality of second conducting wires on a first lateral surface and a second lateral surface of the icon layer respectively, while covering the first conducting wires onto a surface of the transparent insulating layer, and installing a plurality of insulating blocks arranged with an interval from each other on the first conducting wires, and finally installing a plurality of first sensing blocks and a plurality of second sensing blocks, and covering the first sensing blocks on the first conducting wires on both sides of the insulating blocks, and the second sensing blocks are connected to other two sides of the insulating blocks.

### BRIEF DESCRIPTION OF THE DRAWINGS

FIG. 1 is a flow chart of a first preferred embodiment of the present invention;

FIG. 2A is a first schematic view of a manufacturing flow of a first preferred embodiment of the present invention;

FIG. 2B is a partial cross-section view of Section A-A′ of FIG. 2A;

FIG. 2C is a partial cross-section view of Section B-B′ of FIG. 2A;

FIG. 3A is a second schematic view of a manufacturing flow of a first preferred embodiment of the present invention;

FIG. 3B is a partial cross-section view of Section A-A′ of FIG. 3A;

FIG. 3C is a partial cross-section view of Section B-B′ of FIG. 3A;

FIG. 4A is a third schematic view of a manufacturing flow of a first preferred embodiment of the present invention;

FIG. 4B is a partial cross-section view of Section A-A′ of FIG. 4A;

FIG. 4C is a partial cross-section view of Section B-B′ of FIG. 4A;

FIG. 5A is a fourth schematic view of a manufacturing flow of a first preferred embodiment of the present invention;

FIG. 5B is a partial cross-section view of Section A-A′ of FIG. 5A;

FIG. 5C is a partial cross-section view of Section B-B′ of FIG. 5A;

FIG. 6 is a flow chart of a second preferred embodiment of the present invention;

FIG. 7A is a first schematic view of a manufacturing flow of a second preferred embodiment of the present invention;

FIG. 7B is a partial cross-section view of Section A-A′ of FIG. 7A;

FIG. 7C is a partial cross-section view of Section B-B′ of FIG. 7A;

FIG. 8A is a second schematic view of a manufacturing flow of a second preferred embodiment of the present invention;

FIG. 8B is a partial cross-section view of Section A-A′ of FIG. 8A;

FIG. 8C is a partial cross-section view of Section B-B′ of FIG. 8A;

FIG. 9A is a third schematic view of a manufacturing flow of a second preferred embodiment of the present invention;

FIG. 9B is a partial cross-section view of Section A-A′ of FIG. 9A;

FIG. 9C is a partial cross-section view of Section B-B′ of FIG. 9A;

FIG. 10A is a fourth schematic view of a manufacturing flow of a second preferred embodiment of the present invention;

FIG. 10B is a partial cross-section view of Section A-A′ of FIG. 10A;

FIG. 10C is a partial cross-section view of Section B-B′ of FIG. 10A;

FIG. 11 is a flow chart of a third preferred embodiment of the present invention;

FIG. 12A is a first schematic view of a manufacturing flow of a third preferred embodiment of the present invention;

FIG. 12B is a partial cross-section view of Section A-A′ of FIG. 12A;

FIG. 12C is a partial cross-section view of Section B-B′ of FIG. 12A;

FIG. 13A is a second schematic view of a manufacturing flow of a third preferred embodiment of the present invention;

FIG. 13B is a partial cross-section view of Section A-A′ of FIG. 13A;

FIG. 13C is a partial cross-section view of Section B-B′ of FIG. 13A;

FIG. 14A is a third schematic view of a manufacturing flow of a third preferred embodiment of the present invention;

FIG. 14B is a partial cross-section view of Section A-A′ of FIG. 14A;

FIG. 14C is a partial cross-section view of Section B-B′ of FIG. 14A;

FIG. 15A is a fourth schematic view of a manufacturing flow of a third preferred embodiment of the present invention;

FIG. 15B is a partial cross-section view of Section A-A′ of FIG. 15A;

FIG. 15C is a partial cross-section view of Section B-B′ of FIG. 15A;

FIG. 16A is a fifth schematic view of a manufacturing flow of a third preferred embodiment of the present invention;

FIG. 16B is a partial cross-section view of Section A-A′ of FIG. 16A;

FIG. 16C is a partial cross-section view of Section B-B′ of FIG. 16A;

FIG. 17 is a flow chart of a fourth preferred embodiment of the present invention;

FIG. 18A is a first schematic view of a manufacturing flow of a fourth preferred embodiment of the present invention;

FIG. 18B is a partial cross-section view of Section A-A′ of FIG. 18A;

FIG. 18C is a partial cross-section view of Section B-B′ of FIG. 18A;

FIG. 19A is a second schematic view of a manufacturing flow of a fourth preferred embodiment of the present invention;

FIG. 19B is a partial cross-section view of Section A-A′ of FIG. 19A;

FIG. 19C is a partial cross-section view of Section B-B′ of FIG. 19A;

FIG. 20A is a third schematic view of a manufacturing flow of a fourth preferred embodiment of the present invention;

FIG. 20B is a partial cross-section view of Section A-A′ of FIG. 20A;

FIG. 20C is a partial cross-section view of Section B-B′ of FIG. 20A;

FIG. 21A is a fourth schematic view of a manufacturing flow of a fourth preferred embodiment of the present invention;

FIG. 21B is a partial cross-section view of Section A-A′ of FIG. 21A;

FIG. 21C is a partial cross-section view of Section B-B′ of FIG. 21A;

FIG. 22A is a fifth schematic view of a manufacturing flow of a fourth preferred embodiment of the present invention;

FIG. 22B is a partial cross-section view of Section A-A′ of FIG. 22A; and

FIG. 22C is a partial cross-section view of Section B-B′ of FIG. 22A.

### DETAILED DESCRIPTION OF THE PREFERRED EMBODIMENTS

The technical characteristics of the present invention will become apparent with the detailed description of preferred embodiments and the illustration of related drawings as follows.

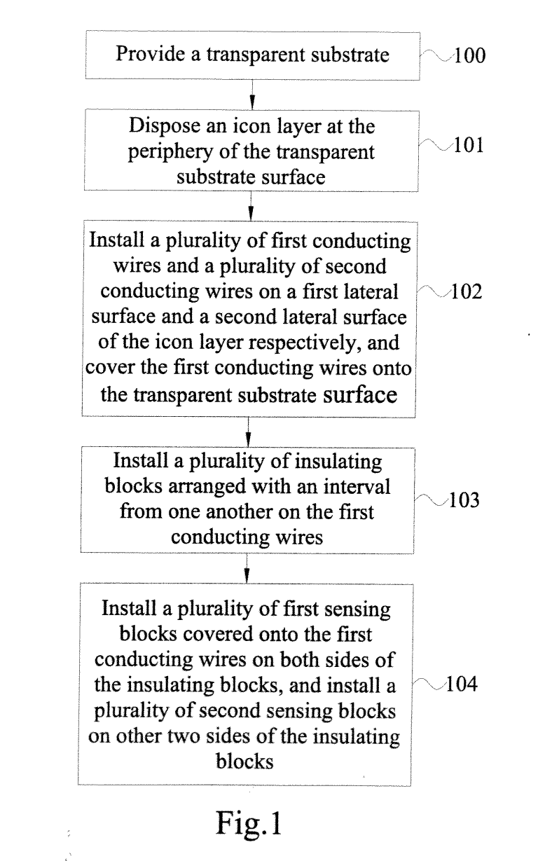

With reference to FIG. 1 for a flow chart of a manufacturing method of a first preferred embodiment of the present invention, the manufacturing method comprises the steps of:

(100) providing a transparent substrate.

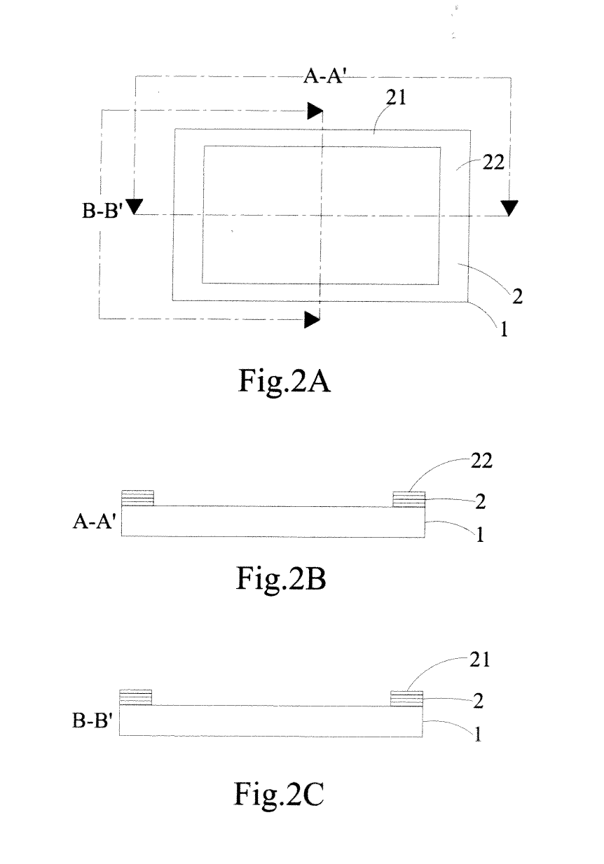

(101) disposing an icon layer at the periphery of the transparent substrate surface, (with reference to FIGS. 2A, 2B and 2C for a first schematic view of a manufacturing flow of a first preferred embodiment of the present invention, the icon layer 2 is disposed on a surface of the transparent substrate 1, and the icon layer 2 is formed by lamination, coating, printing or spray coating, and the icon layer 2 comes with a hollow frame structure, and the transparent substrate 1 is made of plastic, polymer plastic, glass, resin, polyethylene terephthalate (PET), polycarbonate (PC), polyethylene (PE), polyvinyl chloride (PVC), polypropylene (PP), polystyrene (PS), polymethylmethacrylate (PMMA) or a plastic polymer of their mixture);

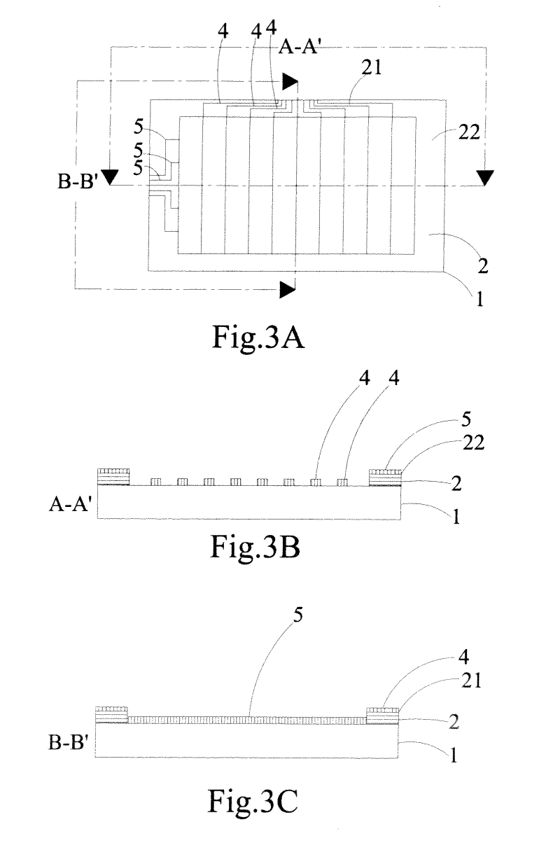

(102) installing a plurality of first conducting wires and a plurality of second conducting wires on a first lateral surface and a second lateral surface of the icon layer respectively, while covering the first conducting wires onto the transparent substrate surface (With reference to FIGS. 3A, 3B and 3C for a second schematic view and partial cross-section views of a manufacturing flow of a first preferred embodiment of the present invention respectively), the first lateral surface 21 or the second lateral surface 22 of the icon layer 2 is not restricted to a lateral surface in any particular direction, and as long as it can satisfy the condition of being perpendicular to the first lateral surface 21 or the second lateral surface 22, and in other words, if any lateral surface of the icon layer 2 is defined as the first lateral surface 21 and the first conducting wires 4 are installed, other two lateral surfaces of the icon layer 2 perpendicular to the first lateral surface 21 are defined as the second lateral surfaces 22, so that the second conducting wires 5 are installed on the second lateral surface 22, or if any lateral surface of the icon layer 2 is defined as the first lateral surface 21 and the second conducting wires 5 are installed, other two lateral surfaces of the icon layer 2 perpendicular to the first lateral surface 21 are defined as the second lateral surfaces 22, so that the first conducting wires 4 are installed on the second lateral surface 22, and the first conducting wire 4 and the second conducting wire 5 are made of chromium, aluminum, silver, molybdenum, copper, gold, highly conductive metals or alloys, and it is noteworthy to point out that when the first conducting wires 4 of this preferred embodiment are installed, the first conducting wires 4 are covered directly onto two corresponding first lateral surfaces 21 of the icon layer 2, such that a portion of the first conducting wires 4 installed between the first lateral surfaces 21 can be covered directly onto a surface of the transparent substrate 1;

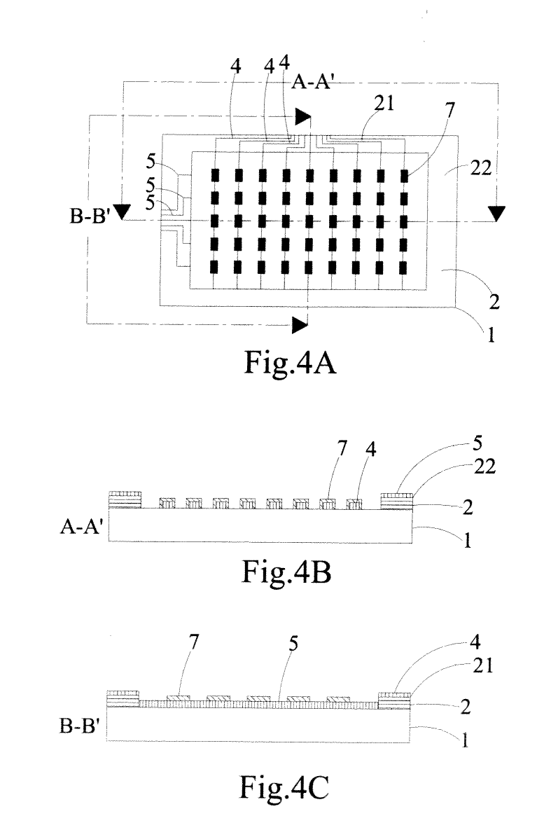

(103) installing a plurality of insulating blocks arranged with an interval from one another on the first conducting wires (with reference to FIGS. 4A, 4B and 4C for a third schematic view and partial cross-section views of a manufacturing flow of a first preferred embodiment of the present invention respectively), the insulating blocks 7 can be installed by lamination, coating, printing or spray coating, and it is noteworthy to point out that when the insulating blocks 7 are arranged, each insulating block 7 is installed alternately with the first conducting wires 4, preferably perpendicularly to each other, and the insulating blocks 7 and the second conducting wires 5 must arranged linearly to each other;

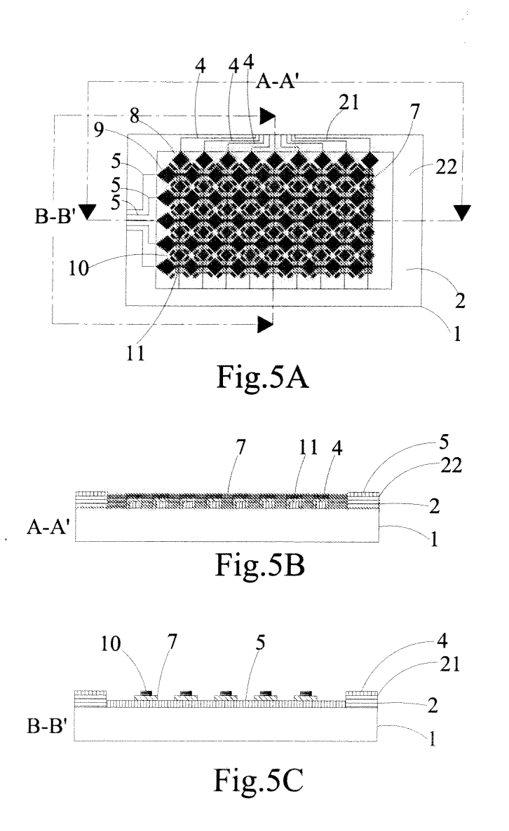

(104) installing a plurality of first sensing blocks covered onto the first conducting wires on both sides of the insulating blocks, while installing a plurality of second sensing blocks on other two sides of the insulating blocks (With reference to FIGS. 5A, 5B and 5C for a fourth schematic view and partial cross-section views of a manufacturing flow of a first preferred embodiment of the present invention respectively), the first sensing blocks 8, the second sensing blocks 9, the modified electrodes 10 and the conductors 11 are installed at the same time, which implies that only one manufacturing process is required for manufacturing the aforementioned components without requiring several manufacturing processes.

The first sensing blocks 8 are installed and arranged on the first conducting wires 4 and disposed at positions corresponding to both sides of each insulating block 7 respectively, and the second sensing blocks 9 are disposed at positions corresponding to other two sides of each insulating block 7, and the conductor 1 is installed on surfaces of the insulating blocks 7 are provided for electrically connecting the second sensing blocks 9. In the figures, each first sensing block 8 and each second sensing block 9 are arranged perpendicular to each other by using the insulating block 7 as a center. The first sensing blocks 8 and the second sensing blocks 9 are made of an impurity-doped oxide such as indium tin oxide (ITO), indium zinc oxide (IZO), Al-doped ZnO (AZO) or antimony tin oxide (ATO) and installed by vacuum sputtering, magnetron sputtering, layer sputtering, spray pyrolysis, pulsed laser deposition, arc discharge ion deposition, respective deposition, ion beam sputtering or chemical vapor deposition, and the first sensing blocks 8 and the second sensing blocks 9 are in the shape of a polygon with three or more sides, preferably in a rhombus shape.

The overall structure of the touch panel structure of the present invention comprises the transparent substrate 1, the icon layer 2 formed on the periphery of a surface of the transparent substrate 1, and the first conducting wire 4 is installed on the first lateral surface 21 of the icon layer 2, while the first conducting wires 4 are covered onto a surface of the transparent substrate 1, and the second conducting wires 5 are installed on the second lateral surface 22 of the icon layer 2, and the plurality of insulating blocks 7 are installed with an interval from each other on the first conducting wires 4, and the first sensing blocks 8 are installed on the first conducting wires 4 on both sides of the insulating blocks 7, and the second sensing blocks 9 are installed on other two sides of the insulating blocks 7.

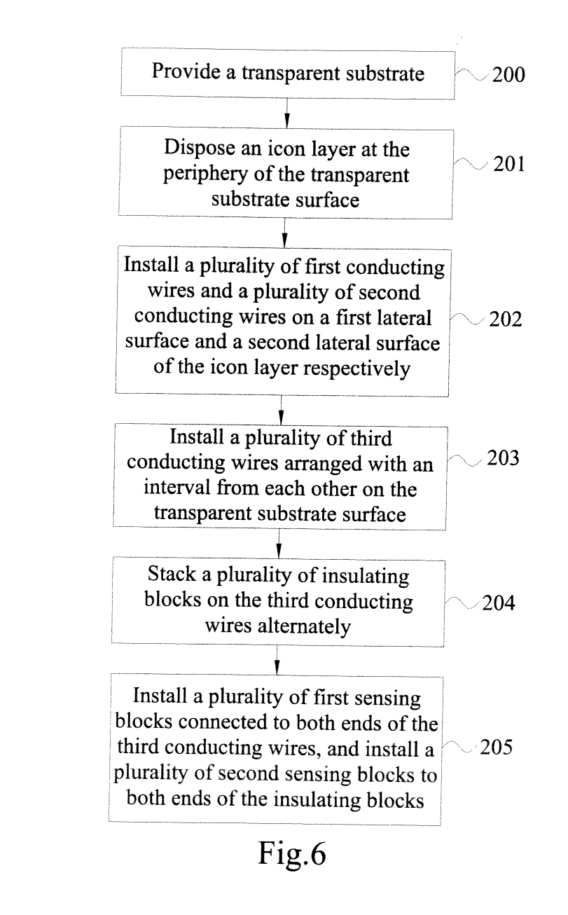

With reference to FIG. 6 for a flow chart of a manufacturing method of a second preferred embodiment of the present invention, the manufacturing method comprises the steps of:

(200) providing a transparent substrate;

(201) disposing an icon layer at the periphery of the transparent substrate surface;

(202) installing a plurality of first conducting wires and a plurality of second conducting wires on a first lateral surface and a second lateral surface of the icon layer respectively;

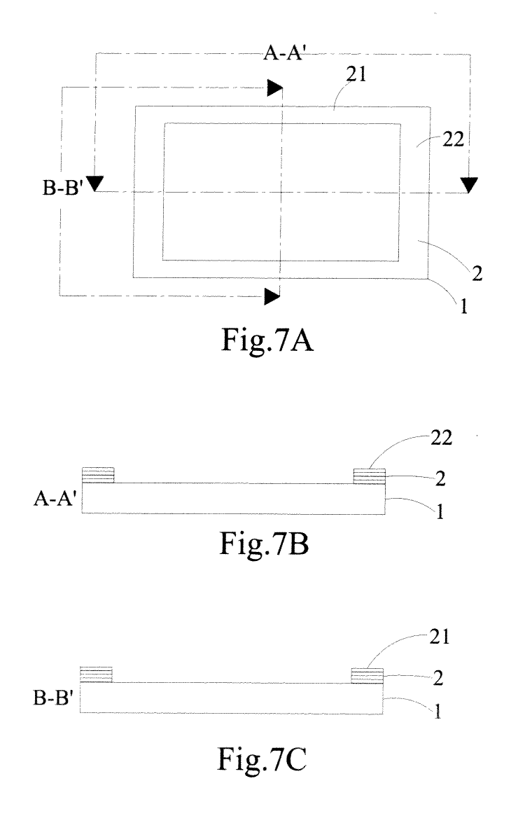

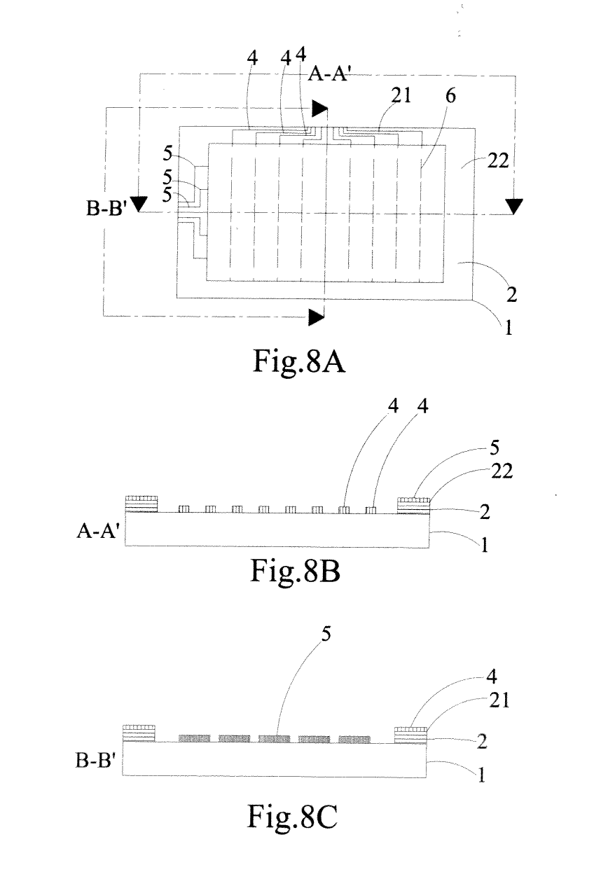

(203) installing a plurality of third conducting wires arranged with an interval from each other on the transparent substrate surface (With reference to FIGS. 7A, 7B, 7C, 8A, 8B and 8C for first and second schematic views and partial cross-section views of a manufacturing flow of a second preferred embodiment of the present invention respectively, the structure and manufacturing procedure from Step (200) to Step (202) are the same as those of the first preferred embodiment, and thus will not be described here again. and unlike the first preferred embodiment, the first conducting wires 4 and the second conducting wires 5 of this preferred embodiment are installed on the first lateral surface 21 and the second lateral surface 22 of the icon layer 2, and thus the third conducting wires 6 arranged with an interval from each other are installed on a surface of an area of the transparent substrate 1 not covered by the icon layer 2, and the third conducting wires 6 and the first conducting wires 4 must be aligned linearly with each other, and the installation and material of the first conducting wire 4, second conducting wire 5 and third conducting wire 6 are the same as those of the first preferred embodiment, and thus will not be described here again);

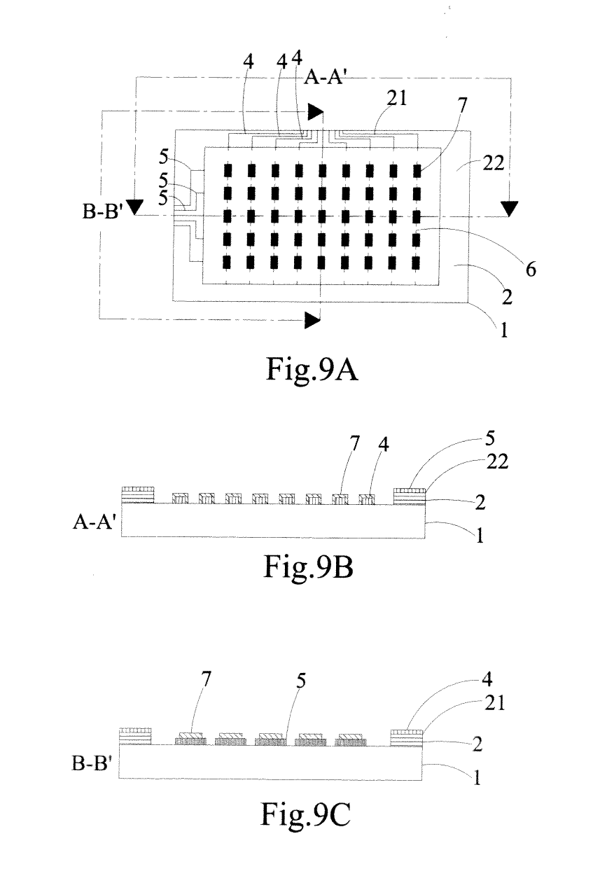

(204) stacking a plurality of insulating blocks on the third conducting wires alternately (With reference to FIGS. 9A, 9B and 9C for a third schematic view of a manufacturing flow of a second preferred embodiment of the present invention, the insulating blocks 7 are installed by lamination, coating, printing or spray coating, and it is noteworthy to point out that when the insulating blocks 7 are arranged, each insulating block 7 is installed alternately with the third conducting wires 6, preferably perpendicular to each other, and the insulating blocks 7 and the second conducting wires 5 must aligned linearly with each other);

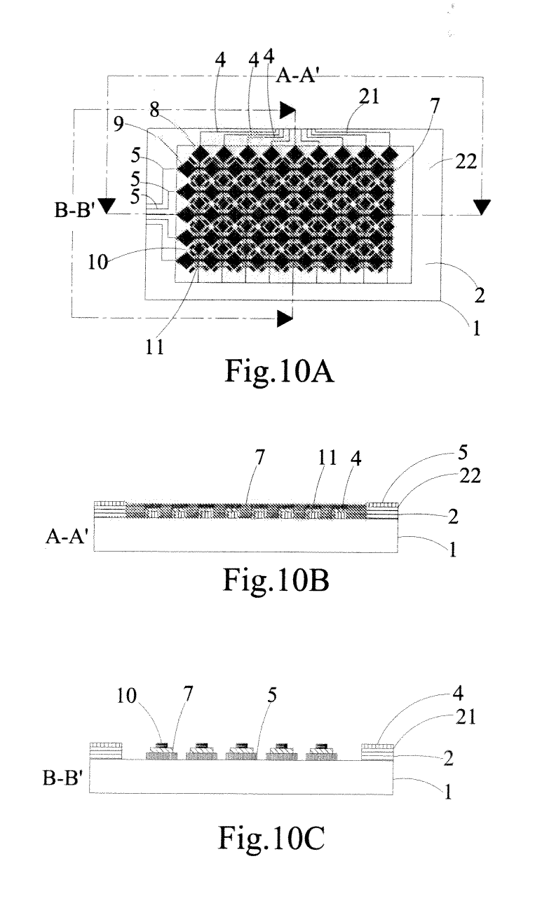

(205) installing a plurality of first sensing blocks connected to both ends of the third conducting wires, while installing a plurality of second sensing blocks to both ends of the insulating blocks (With reference to FIGS. 10A, 10B and 10C for a fourth schematic view and partial cross-section views of a manufacturing flow of a second preferred embodiment of the present invention respectively, the first sensing blocks 8, the second sensing blocks 9, the modified electrodes 10 and the conductors 11 are installed and completed at the same time, which implies that one manufacturing process can be used directly for manufacturing all of the aforementioned components without going through several manufacturing processes, and the structure and manufacturing procedure of the components are the same as those of the first preferred embodiment, and thus will not be described here again).

When the first sensing blocks 8 are installed, the first sensing blocks 8 are arranged between the third conducting wires 6, which implies that the first sensing blocks 8 are disposed at position corresponding to both sides of each insulating block 7 respectively, while each first sensing block 8 is respectively and electrically connected to the two third conducting wires 6, and the second sensing blocks 9 are disposed opposite to each other and corresponding to both sides of each insulating block 7 respectively, and the conductors 11 installed on surfaces of the insulating blocks 7 are provided for electrically connecting the second sensing blocks 9. In the figures, each first sensing block 8 and each second sensing block 9 are arranged perpendicular to each other by using the insulating block 7 as a center.

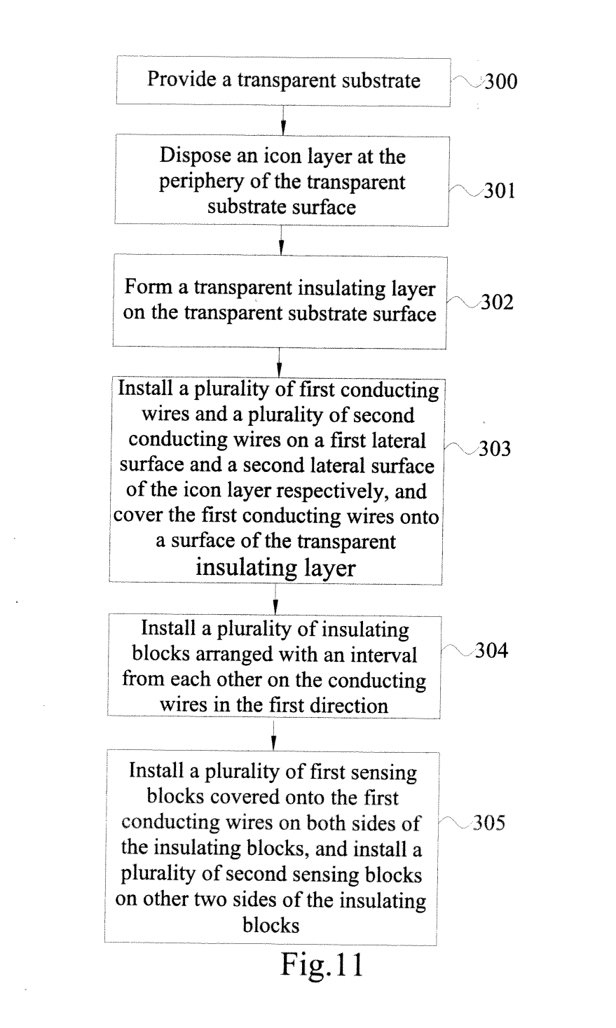

With reference to FIG. 11 for a flow chart of a manufacturing method of a third preferred embodiment of the present invention, the manufacturing method comprises the steps of:

(300) providing a transparent substrate;

(301) disposing an icon layer at the periphery of the transparent substrate surface;

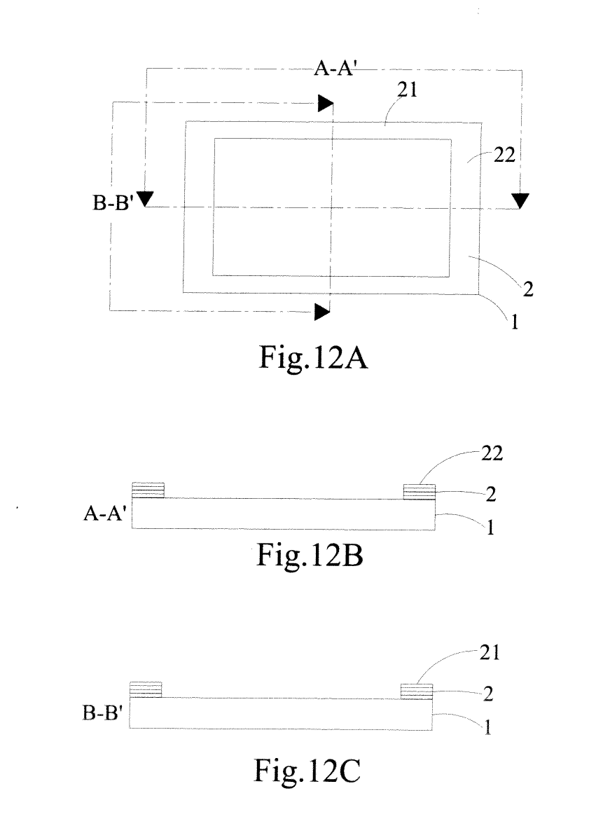

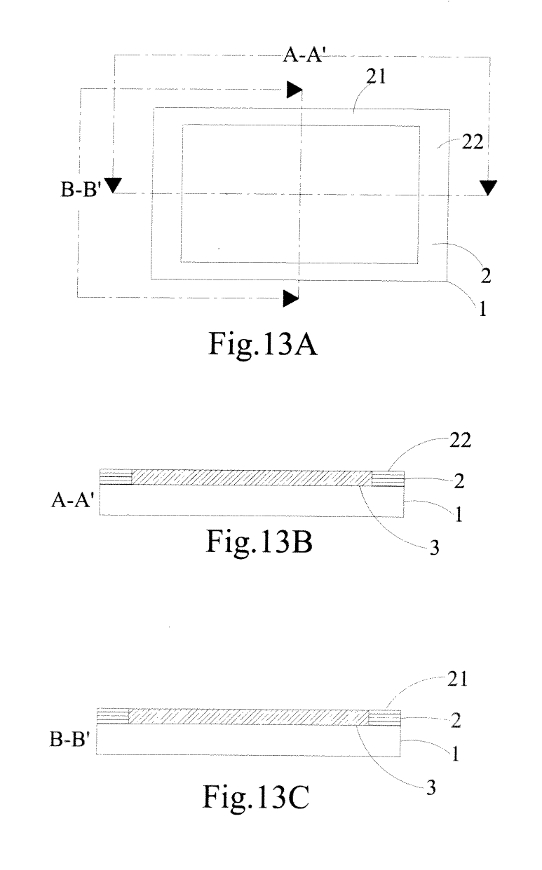

(302) forming a transparent insulating layer on the transparent substrate surface (with reference to FIGS. 12A, 12B, 12C, 13A, 13B and 13C for first and second schematic views and partial cross-section views of a manufacturing flow of a third preferred embodiment of the present invention respectively), the structure and manufacturing procedure from Step (300) to Step (302) are the same as those of the first preferred embodiment, and thus will not described here again. Unlike the first preferred embodiment, the transparent insulating layer 3 is formed on a surface of an area of the icon layer 2 not covered by the transparent substrate 1, and it can be installed by lamination, coating, printing or spray coating);

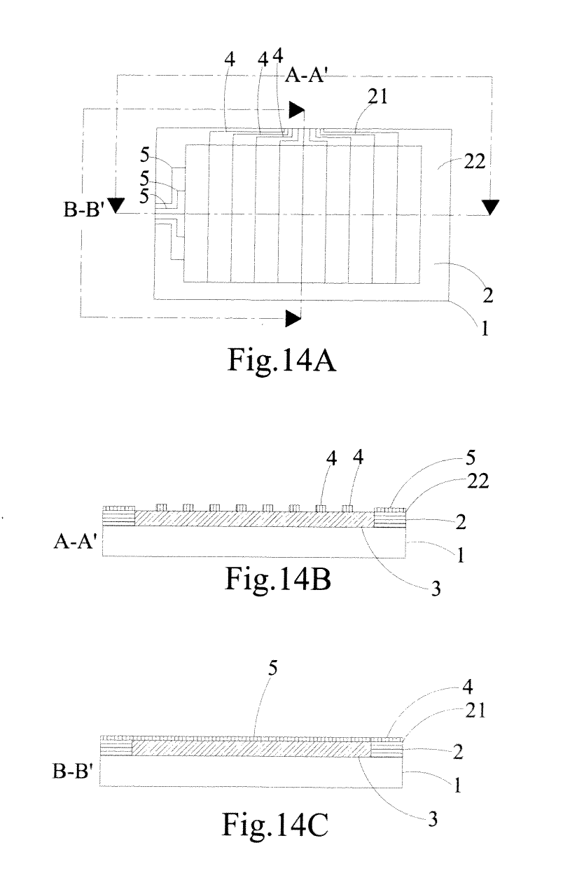

(303) installing a plurality of first conducting wires and a plurality of second conducting wires on a first lateral surface and a second lateral surface of the icon layer respectively, and covering the first conducting wires onto a surface of the transparent insulating layer (with reference to FIGS. 14A, 14B and 14C for a third schematic view and partial cross-section views of a manufacturing flow of a third preferred embodiment of the present invention respectively), the structure and manufacturing procedure are the same as those of the first preferred embodiment, and thus will not be described here again, and the only difference resides on that when the first conducting wires 4 are installed, the first conducting wires 4 are covered directly on the two corresponding first lateral surfaces 21 of the icon layer 2, and thus a portion of the first conducting wires 4 felled between the first lateral surfaces 21 covered onto a surface of the transparent insulating layer 3.

(304) installing a plurality of insulating blocks arranged with an interval from each other on the conducting wires in the first direction; and

(305) installing a plurality of first sensing blocks covered onto the first conducting wires on two sides of the insulating blocks, while installing a plurality of second sensing blocks on other two sides of the insulating blocks.

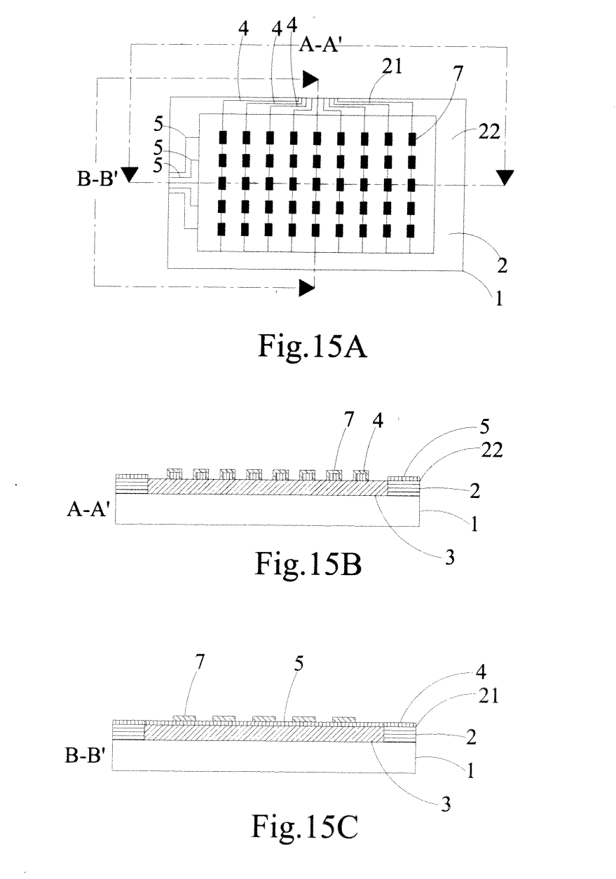

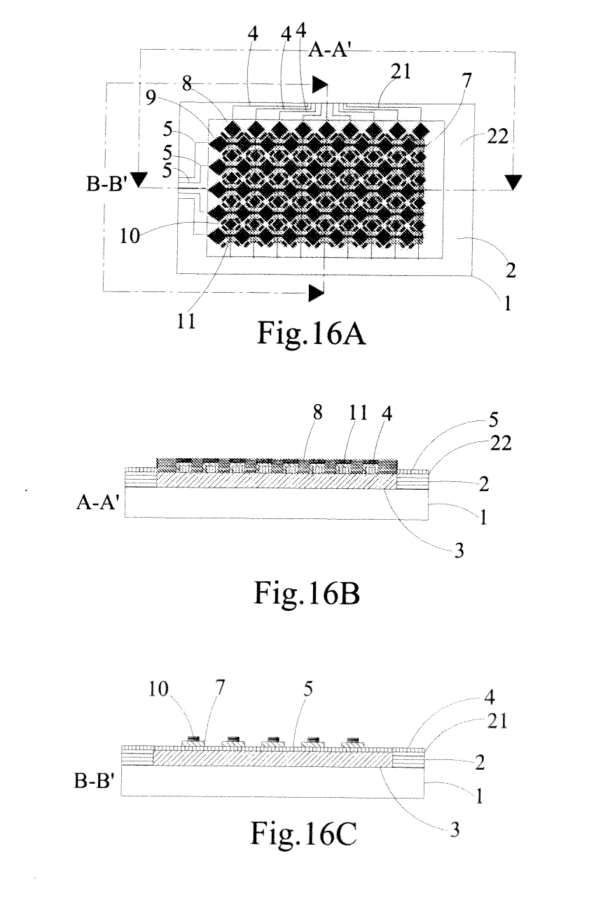

With reference to FIGS. 15A, 15B, 15C, 16A, 16B and 16C for fourth and fifth schematic views and partial cross-section views of a third preferred embodiment of the present invention, the structure and manufacturing procedure of this preferred embodiment are the same as those of the first preferred embodiment, and thus will not be described here again. It is noteworthy to point out that an additional transparent insulating layer 3 is formed in the third preferred embodiment of the present invention, such that the overall structure sequentially comprises the transparent substrate 1, the icon layer 2 formed at the periphery of a surface of the transparent substrate 1, the transparent insulating layer 3 formed on a surface of the transparent substrate 1, the first conducting wire 4 installed on the first lateral surface 21 of the icon layer 2, and the first conducting wires 4 are covered onto a surface of the transparent insulating layer 3, and the second conducting wires 5 are installed on the second lateral surface 22 of the icon layer 2, and the plurality of insulating blocks 7 are arranged with an interval from each other on the first conducting wires 4, and the first sensing blocks 8 are installed on the first conducting wires 4 on both sides of the insulating blocks, and the second sensing blocks 9 are installed on other two sides of the insulating blocks 7. Since the icon layer 2 comes with a hollow frame structure, and the transparent insulating layer 3 is added to reduce the height difference between the icon layer 2 and its internal hollow area, therefore the climbing effect of the components installed adjacent to the icon layer 2 can be reduced when the first conducting wires 4, the second conducting wires 5, the first sensing blocks 8 and the second sensing blocks 9 are installed, so as to reduce the poor sensing condition at the edges of the sensing area in a touch sensing operation.

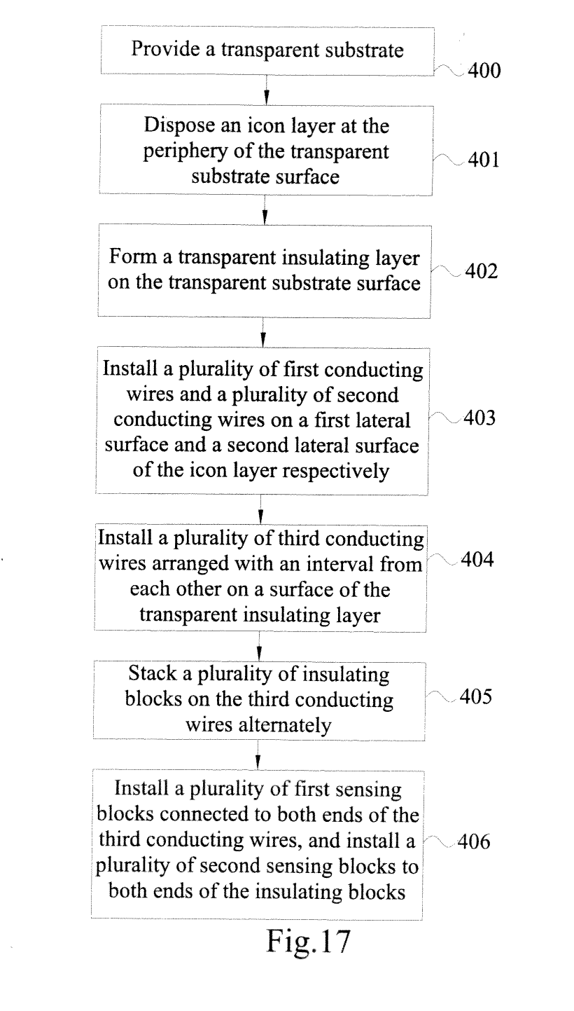

With reference to FIG. 17 fora flow chart of a manufacturing method of a fourth preferred embodiment of the present invention, the manufacturing method comprises the steps of:

(400) providing a transparent substrate;

(401) forming an icon layer at the periphery of the transparent substrate surface:

(402) forming a transparent insulating layer on the transparent substrate surface;

(403) installing a plurality of first conducting wires and a plurality of second conducting wires on a first lateral surface and a second lateral surface of the icon layer respectively;

(404) installing a plurality of third conducting wires arranged with an interval from each other on a surface of the transparent insulating layer;

(405) stacking a plurality of insulating blocks on the third conducting wires alternately; and

(406) installing a plurality of first sensing blocks connected to both ends of the third conducting wires, while installing a plurality of second sensing blocks to both ends of the insulating blocks.

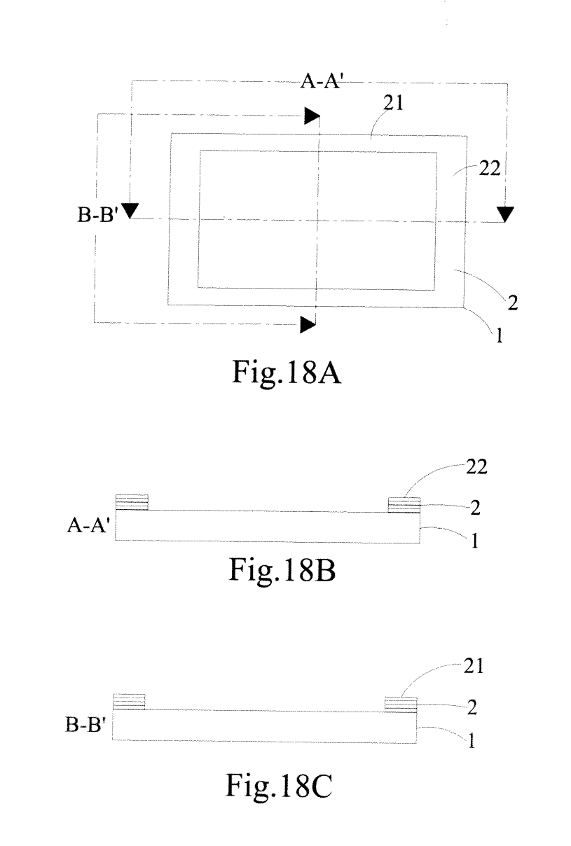

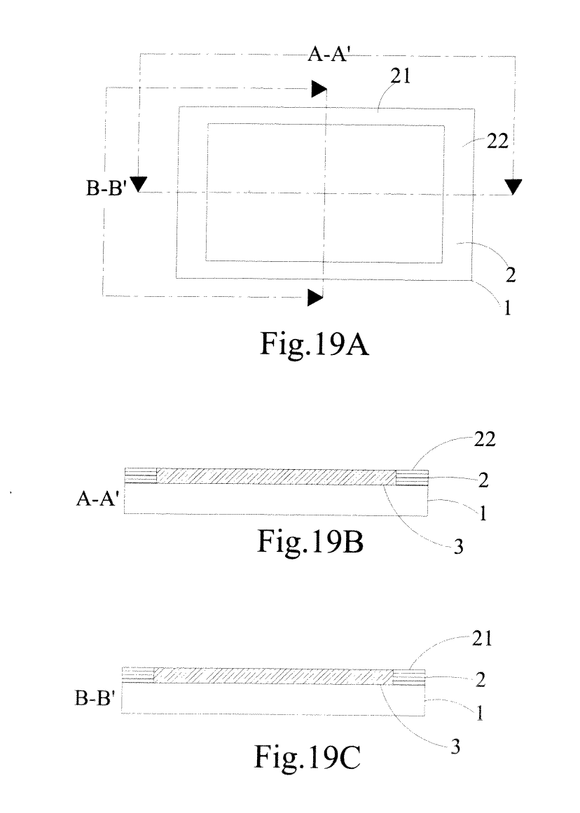

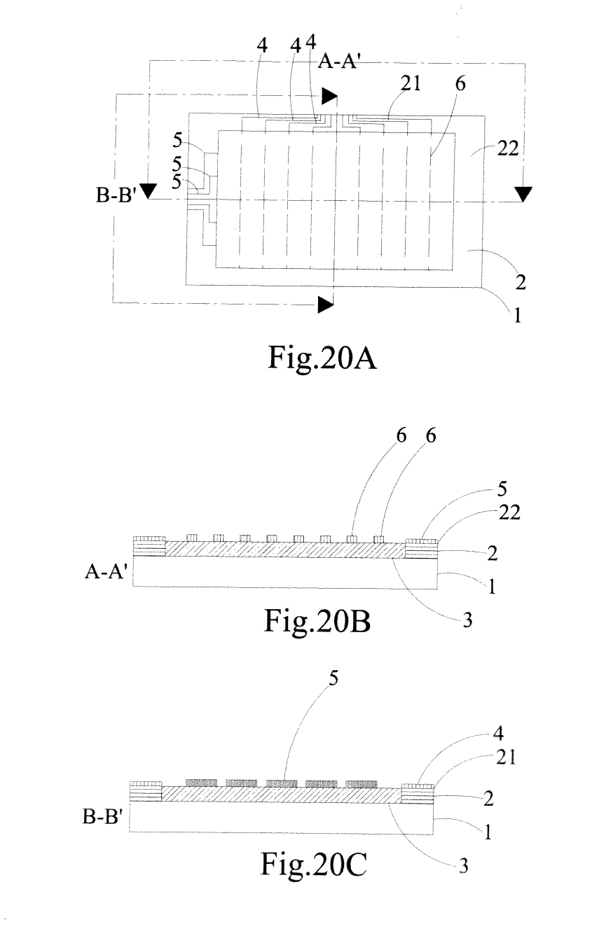

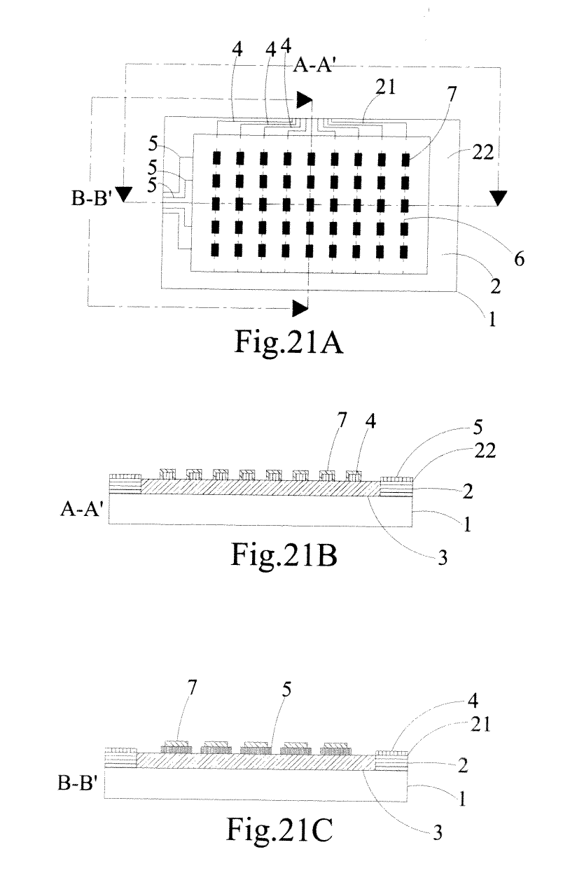

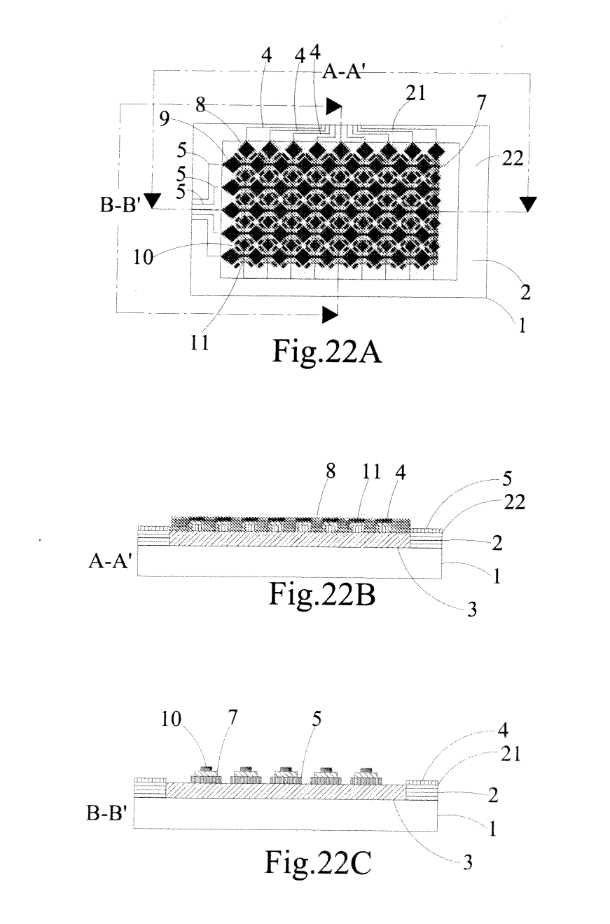

With reference to FIGS. 18A to 22C, the difference of the second and fourth preferred embodiments of the present invention resides on that the transparent insulating layer 3 is added in the fourth preferred embodiment to achieve reducing the climbing effect generated by components installed adjacent to the icon layer 2, so as to reduce the poor sensing effect at the edges of the sensing area, while the remaining structure and the manufacturing procedure are the same as those of the first preferred embodiment, and thus will not be described here again.

In summation of the description above, the invention can improve over the prior art and comply with the patent application requirements, and thus is duly filed for patent application.

While the invention has been described by device of specific embodiments, numerous modifications and variations such as the type, shape, and size of the casing or the type of the multi-stage switch and knob could be made thereto by those generally skilled in the art without departing from the scope and spirit of the invention set forth in the claims.

What is claimed is:

1. A touch panel manufacturing method, comprising the steps of:
providing a transparent substrate;
disposing an icon layer at the periphery of the transparent substrate surface;
installing a plurality of first conducting wires and a plurality of second conducting wires on a first lateral surface and a second lateral surface of the icon layer respectively;
installing a plurality of insulating blocks arranged with an interval from each other on the first conducting wires; and
installing a plurality of first sensing blocks covered onto the first conducting wires on both sides of the insulating blocks, while installing a plurality of second sensing blocks on both sides of the insulating blocks.

2. The touch panel manufacturing method of claim 1, wherein the transparent substrate is made of a material selected from the collection of plastic, polymer plastic and glass, or a material selected from the collection of resin, polyethylene terephthalate (PET), polyccarbonate (PC), polyethylene (PE), polyvinyl chloride (PVC), polypropylene (PP), polystyrene (PS) and polymethylmethacrylate (PMMA), or a plastic polymer of their mixture.

3. The touch panel manufacturing method of claim 1, wherein the first conducting wires and the second conducting wires are made of a material selected from the collection of chromium, aluminum, silver, molybdenum, copper, gold, highly conductive metals and alloys.

4. The touch panel manufacturing method of claim 1, wherein the first sensing blocks and the second sensing blocks are impurity-doped oxides selected from the collection of indium tin oxide (ITO), indium zinc oxide (IZO), Al-doped ZnO (AZO) and antimony tin oxide (ATO).

5. The touch panel manufacturing method of claim 1, wherein the first sensing blocks and the second sensing blocks are formed by a method selected from the collection of vacuum sputtering, magnetron sputtering, layer sputtering, spray pyrolysis, pulsed laser deposition, arc discharge ion deposition, reactive deposition, ion beam sputtering or chemical vapor deposition.

6. The touch panel manufacturing method of claim 1, wherein each first sensing block and each second sensing block are arranged perpendicular to each other by using the insulating block as a center.

7. The touch panel manufacturing method of claim 1, wherein each insulating block includes a conductor installed on a surface of the insulating block and provided for an electric connection between the second sensing blocks.

8. The touch panel manufacturing method of claim 1, wherein the first lateral surface and the second lateral surface of the icon layer are perpendicular to each other.

9. The touch panel manufacturing method of claim 1, wherein the icon layer is installed by lamination, coating, printing or spray coating.

10. The touch panel manufacturing method of claim 1, further comprising a modified electrode disposed between the first sensing blocks and the second sensing blocks.

11. The touch panel manufacturing method of claim 1, wherein the step of forming the icon layer at the periphery of the transparent substrate surface further comprising the step of forming a transparent insulating layer on the transparent substrate surface.

12. The touch panel manufacturing method of claim 11, wherein the icon layer is installed by lamination, coating, printing or spray coating.

13. A touch panel manufacturing method, comprising the steps of:
providing a transparent substrate;
disposing an icon layer at the periphery of the transparent substrate surface;
installing a plurality of first conducting wires and a plurality of second conducting wires on a first lateral surface and a second lateral surface of the icon layer respectively;
installing a plurality of third conducting wires arranged with an interval with each other in an area of the transparent substrate surface without being covered by the icon layer;
stacking a plurality of insulating block alternately on the third conducting wires; and
installing a plurality of first sensing blocks connected to both ends of the third conducting wires, while installing a plurality of second sensing blocks at both ends of the insulating blocks.

14. The touch panel manufacturing method of claim 13, wherein the transparent substrate is made of a material selected from the collection of plastic, polymer plastic and glass, or a material selected from the collection of resin, Polyethylene terephthalate (PET), polycarbonate (PC), polyethylene (PE), polyvinyl chloride (PVC), polypropylene (PP), polystyrene (PS) and polymethylmethacrylate (PMMA), or a plastic polymer of their mixture.

15. The touch panel manufacturing method of claim 13, wherein the first conducting wires, the second conducting wires and the third conducting wires are made of a material selected from the collection of chromium, aluminum, silver, molybdenum, copper, gold, highly conductive metal and alloy.

16. The touch panel manufacturing method of claim 13, wherein the first sensing blocks and the second sensing blocks are impurity-doped oxides selected from the collection of indium tin oxide (ITO), indium zinc oxide (IZO), Al-doped ZnO (AZO) and antimony tin oxide (ATO).

17. The touch panel manufacturing method of claim 13, wherein the first sensing blocks and the second sensing blocks are installed by vacuum sputtering, magnetron sputtering, layer sputtering, spray pyrolysis, pulsed laser deposition, arc discharge ion deposition, reactive deposition, ion beam sputtering or chemical vapor deposition.

18. The touch panel manufacturing method of claim 13, wherein each first sensing block and each second sensing block are arranged perpendicular to each other by using the insulating block as a center.

19. The touch panel manufacturing method of claim 13, wherein each insulating block includes a conductor installed on a surface of the insulating block and provided for an electric connection between the second sensing blocks.

20. The touch panel manufacturing method of claim 13, wherein the icon layer is installed by lamination, coating, printing or spray coating.

21. The touch panel manufacturing method of claim 13, further comprising a modified electrode installed between the first sensing blocks and the second sensing blocks.

22. The touch panel manufacturing method of claim 13, wherein the step of forming the icon layer at the periphery of the transparent substrate surface further comprises the step of installing a transparent insulating layer on the transparent substrate surface.

23. The touch panel manufacturing method of claim 22, wherein the transparent insulating layer is installed by lamination, coating, printing or spray coating.

24. A touch panel structure, comprising:
a transparent substrate;
an icon layer, disposed at the periphery of the transparent substrate surface;
a plurality of first conducting wires, installed on a first lateral surface of the icon layer, and covered onto the transparent substrate surface;
a plurality of second conducting wires, installed on a second lateral surface of the icon layer;
a plurality of insulating blocks, arranged with an interval from each other on the first conducting wires;
a plurality of first sensing blocks, installed at the first conducting wires on two sides of the insulating blocks; and
a plurality of second sensing blocks, installed on other two sides of the insulating blocks.

25. The touch panel structure of claim 24, wherein the transparent substrate is made of a material selected from the collection of plastic, polymer plastic and glass, or a material selected from the collection of resin, polyethylene terephthalate (PET), polyccarbonate (PC), polyethylene (PE), polyvinyl chloride (PVC), polypropylene (PP), polystyrene (PS) and polymethylmethacrylate (PMMA), or a plastic polymer of their mixture.

26. The touch panel structure of claim 24, wherein the first conducting wires and the second conducting wires are made of a material selected from the collection of chromium, aluminum, silver, molybdenum, copper, gold, highly conductive metals and alloys.

27. The touch panel structure of claim 24, wherein the first sensing blocks and the second sensing blocks are impurity-doped oxides selected from the collection of indium tin oxide (ITO), indium zinc oxide (IZO), Al-doped ZnO (AZO) and antimony tin oxide (ATO).

28. The touch panel structure of claim 24, wherein the first sensing blocks and the second sensing blocks are installed by vacuum sputtering, magnetron sputtering, layer sputtering, spray pyrolysis, pulsed laser deposition, arc discharge ion deposition, reactive deposition, ion beam sputtering or chemical vapor deposition.

29. The touch panel structure of claim 24, wherein each first sensing block and each second sensing block are arranged perpendicular to each other by using the insulating block as a center.

30. The touch panel structure of claim 24, wherein each insulating block includes a conductor installed on a surface of the insulating block and provided for an electric connection between the second sensing blocks.

31. The touch panel structure of claim 24, wherein the icon layer is installed by lamination, coating, printing or spray coating.

32. The touch panel structure of claim 24, wherein the first lateral surface and the second lateral surface of the icon layer are perpendicular to each other.

33. The touch panel structure of claim 24, wherein the transparent substrate surface includes a transparent insulating layer.

34. The touch panel structure of claim 33, therein the transparent insulating layer is installed by lamination, coating, printing or spray coating.

35. The touch panel structure of claim 24, further comprising a modified electrode installed between the first sensing blocks and the second sensing blocks.
